(19) United States
(12) Patent Application Publication
(10) Pub. No.: US 2014/0266262 A1
(43) Pub. Date: Sep. 18, 2014

(54) HIGH RESOLUTION FINGERPRINT IMAGING DEVICE

(71) Applicant: PERKINELMER HOLDINGS, INC., Waltham, MA (US)

(72) Inventor: Farhad TAGHIBAKHSH, Santa Clara, CA (US)

(73) Assignee: PERKINELMER HOLDINGS, INC., Waltham, MA (US)

(21) Appl. No.: 13/831,454

(22) Filed: Mar. 14, 2013

(51) Int. Cl. G01R 27/26

(52) U.S. Cl. CPC G01R 27/2605
USPC 324/686

(57) ABSTRACT

A fingerprint sensor pixel and fingerprint imaging device are disclosed. A fingerprint sensor pixel includes a capacitive sensor and a readout circuit. The capacitance of the capacitive sensor changes in response to contact with a fingerprint. The readout circuit includes a first thin film transistor (TFT) used to convert the capacitance of the capacitive sensor to a representative current, a coupling capacitor used to capacitively couple a readout pulse to the gate of the said second TFT sharing the connection with the capacitive sensor pixel, and a second TFT used to reset the voltage of the capacitive sensor. Multiple fingerprint sensor pixels can be arranged in an array to form a fingerprint imaging device.

### BACKGROUND

1. Field

This application relates generally to fingerprint imaging devices, and, more specifically, to readout circuitry for capacitive sensors used in fingerprint imagers.

2. Description of the Related Art

A sensor pixel consists of a detector and an electronic readout circuit. The sensor pixel is operated via connection to peripheral circuits (e.g., biasing, addressing, readout and digitizer circuitries). Individual sensor pixels can be arranged in a matrix to form an array. In imaging applications, the signal from each sensor pixel in the array can be read and arranged (i.e., multiplexed) to generate a digital electronic image.

One specific application of sensor pixel arrays is biometric detection of fingerprints and handprints. Sensors for such applications need to be large (to cover all five fingers), fast, and have high resolution (e.g., around 50 micron pitch). A fingerprint imaging sensor includes an array of detectors that each sense a portion of a fingerprint to form an image. Fingerprint sensors may be used, for example, to recognize the pattern of a human fingerprint and provide identification information. Fingerprint sensors are widely used in products such as mobile phones or notebooks, often for security purposes, and are critically important to homeland security.

Fingerprint imaging devices may use capacitive sensor arrays. In general, a capacitor contains two metal plates separated by a distance d. A dielectric material may be placed between the plates. The capacitance of the capacitor is inversely proportional to the distance between the plates, and is represented by the equation:

$$C = \frac{{ɛ}_{o} {ɛ}_{r} A}{t}$$

where ∈ₒ is the permittivity of vacuum, ∈ᵣ is the relative dielectric constant of the material between the plates, A is the common area of the two plates, and t is the thickness of the dielectric between the two plates.

A pixilated capacitive sensor can be designed in such a way that the finger skin forms one plate of the sensor capacitor, so that the value of the sensor capacitance depends on whether a ridge or a valley of a finger print is placed against the sensor pixel.

The sensor pixel readout circuit used to read the sensor value (i.e., to readout the convert the capacitive sensor charge or to convert the capacitance value into a representative voltage or current) may be passive or active. In a passive pixel sensor (PPS), signal charge is accumulated on the sensor pixel capacitance is transferred to an external charge amplifier during a readout/reset cycle using a transistor switch that connects the pixel sensor capacitance to an external charge integrator or charge amplifier. The transferred charge is converted to an equivalent voltage in the charge amplifier and is then further processed. FIG. 1 shows sensor pixel 100, which has a PPS configuration and includes a capacitive fingerprint sensor C_{R}. When switch SW is closed, the pixel is in a charging stage where the pixel capacitance C_{R} is charged from the constant biasing voltage V_{A} and according to its capacitance which is modulated by the fingerprint. The charge is then read out by applying a voltage signal to scan line SL large enough to turn transistor T1 ON. The signal charge transferred to the output RL when T1 is ON is representative of the capacitance of sensor C_{R}.

In an active pixel sensor (APS), amplification of the signal is performed on the pixel in the readout circuit. The amplification may be performed, for example, by an on-pixel transistor amplifier that converts the sensor signal to an equivalent output current or voltage. An APS that converts the pixel capacitor signal to a representative voltage or current is faster to operate because the signal can be read directly such that charge integration is not required. Also, an APS has high gain because the signal at the sensor is effectively amplified at the source terminal of the transistor, providing better immunity to external noise sources. FIG. 2 shows APS 200 using a generic sensor. As shown in FIG. 2, APS 200 includes three field effect transistors (FET). T2 is used to reset the voltage at the sensor, and an on-pixel transconductance amplifier T1 converts the sensor voltage to an equivalent output current. Since the capacitor Cₚᵢₓ is not discharged, a constant current is provided at the output as long as transistor T3 is ON. However, the APS uses three transistors compared to one used in the PPS, which can increase the size of the pixel and reduce the resolution of an array unless APS circuits with reduced number of on-pixel elements are used.

Also, as in many imaging applications, modern fingerprint imagers require the ability to capture images quickly. Shorter frame times are desirable for improving signal-to-noise ratio and reducing image blur. However, the ability to read out the sensor values of an array becomes an issue when using very large arrays because of the number of pixels in the array and the increased physical size of the array. Slow transfer times increase the total amount of time required to read the signals from all the pixels in the array, which reduces the number of frame images that can be captured per second (i.e., reduced frame rate or increased frame time).

To increase readout rates, the transistors in modern large area fingerprint imagers are typically made using technologies such as poly-silicon or CMOS that have very fast switching speeds. Although these technologies provide fast electronic readout, circuit elements formed from poly-silicon and CMOS are expensive compared to elements formed from materials such as amorphous silicon (a-Si) or amorphous metal oxide (a-MO) alloy semiconductors such as indium gallium zinc oxide (IGZO) alloys particularly if large area imagers such as full hand scanners are considered.

Thus, there is an opportunity to improve the speed, size, cost, and resolution of fingerprint imaging sensors by employing capacitive sensors to novel active readout circuits and use of materials that provide better electronic properties.

### SUMMARY

Circuit configurations for improving the performance of fingerprint sensor pixels and fingerprint imaging devices are disclosed. The sensor pixels require only two transistors, which can reduce the size of the pixels and allow for higher resolution imaging. The circuits can operate with high gain to amplify the output of a capacitive fingerprint sensor.

In one embodiment, a fingerprint sensor pixel includes a capacitive sensor and a readout circuit. The capacitance of the capacitive sensor changes in response to contact with a fingerprint. When the ridge of a finger is placed on the pixel capacitor (i.e., the capacitive sensor), its capacitance increases compared to when the valley of the fingerprint is on the pixel capacitor. The readout circuit includes a first thin film transistor (TFT) that resets the voltage of the pixel capacitor using a constant voltage source. For example, the drain/source of the first TFT is connected to the pixel capacitor and its source/drain is connected to the biasing voltage source. The readout circuit also includes a second active TFT that is switched ON and OFF through a coupling capacitor and converts the voltage of the capacitive sensor to a representative current or voltage at the output of the pixel. The drain of the second TFT is connected to a biasing voltage, and its source forms the output of the pixel, while its gate is connected to the capacitive sensor and shares the node with the coupling capacitor and the drain/source of the first TFT.

In one embodiment, a fingerprint imaging device includes a plurality of fingerprint sensor pixels forming a two-dimensional fingerprint sensor array. Each fingerprint sensor pixel of the plurality of fingerprint sensor pixels includes a capacitive sensor, and a readout circuit having a first TFT for resetting the pixel sensor capacitance and a second active TFT for reading the pixel sensor value to a representative current or voltage at the pixel output, while the second TFT is turned ON/OFF using a coupling capacitor connected to its gate. The capacitance of the capacitive sensor changes in response to contact with a fingerprint.

In one embodiment, the fingerprint imaging device includes a scan line associated with each row of a fingerprint sensor array which is connected to the coupling capacitor of all the pixels in the row of the fingerprint sensor array. The scan line is connected to the gates of all resetting TFTs of one of the neighboring rows of the fingerprint sensor array, so that, when the sensor values of pixels of a row are being read out, the pixel capacitors of the neighboring row are reset.

In another embodiment, the fingerprint imaging device includes a scan line associated with a row of a fingerprint sensor array which is connected to the coupling capacitor of pixels in the row of the fingerprint sensor array. The gates of the resetting TFTs of the fingerprint sensor array are connected to a global reset line, so that, when the global reset is activated the pixel capacitors in the array are reset.

In another embodiment, the fingerprint imaging device includes a gate driver module and a multiplexing module formed on the same substrate panel as the fingerprint sensor array.

### DESCRIPTION OF THE FIGURES

FIG. 1 depicts a diagram of a passive pixel sensor having a capacitive sensor;

FIG. 2 depicts a diagram of a three-transistor active pixel sensor;

FIG. 3 depicts a diagram of an exemplary two-transistor active pixel sensor having a capacitive sensor;

FIG. 4A depicts a diagram of an exemplary imaging sensor array with automatic reset;

FIG. 4B depicts a diagram of an exemplary imaging sensor array with global reset;

FIGS. 5A-C depict a diagram of an exemplary two-transistor active pixel sensor circuit having a capacitive sensor, the driving pulses, and simulated output response for simulated valley and ridge capacitances;

FIG. 6 depicts a diagram of an exemplary two-transistor active pixel sensor having a capacitive sensor with reset voltage equal to low voltage of the scan line;

FIG. 7 depicts a diagram of an exemplary two-transistor active pixel sensor including a capacitive sensor having an independent reset voltage;

FIG. 8 depicts a diagram of an exemplary fingerprint imaging detector panel having an active pixel sensor array, gate driver and output multiplexing units formed on the same substrate connected to external control and ADC units; and

FIG. 9 depicts a diagram of an exemplary fingerprint imaging detector panel having an active pixel sensor array connected to external gate driver, output multiplexing, control and ADC units.

The figures depict embodiments of the present invention for purposes of illustration only. One skilled in the art will readily recognize from the following discussion that alternative embodiments of the structures and methods illustrated herein can be employed without departing from the principles of the invention described herein.

### DETAILED DESCRIPTION

The following description sets forth numerous specific configurations, parameters, and the like. It should be recognized, however, that such description is not intended as a limitation on the scope of the present invention, but is instead provided as a description of exemplary embodiments.

The present disclosure provides active circuits to readout a signal from a capacitive fingerprint sensor that provides better resolution, faster readout speed. As mentioned above, modern large area fingerprint imagers are typically made using expensive technologies such as poly-silicon or CMOS. Although expensive, circuit elements formed from poly-silicon and CMOS have very fast switching speeds compared to elements formed from less expensive materials such as amorphous silicon. The circuits described herein make it possible to realize large area fingerprint sensors using the less expensive amorphous silicon or amorphous metal oxide semiconductor technologies. The sensor array is configured in such a way that it can be fabricated using amorphous silicon technology and meet the speed and resolution requirements that are traditionally available to other technologies such as poly-silicon and/or CMOS. The circuits propose an active high performance readout circuit at the pixel level with only two transistors. Having fewer on-pixel transistors than a standard three-transistor APS is a feature of the embodiments. Fewer transistors reduce the area taken up by each pixel, which can enable higher pixel density and higher image resolution.

In one embodiment, there is a sensor pixel comprising a capacitive sensor for generating a signal in response to a ridge or a valley of a fingerprint placed upon the pixel sensor, and readout circuitry operatively coupled to the sensor. The readout circuitry is configured to generate an output signal representative of the capacitance of the sensor. For example, the amplitude of the output signal may represent the sensor capacitance. The readout circuitry comprises a coupling capacitor and two TFTs. One TFT operates as a switch and the other as an amplifier. The coupling capacitor is coupled to the gate terminal of the amplifier TFT and the drain terminal of the switch TFT. A voltage pulse applied to the coupling capacitor can turn the amplifier TFT ON and the current flowing between its drain and source terminals can be modulated by its gate-source voltage which is determined by the pixel sensor capacitance. In another embodiment, an array of such sensor pixels is provided which is capable of generating an image of the fingerprint placed upon it.

FIG. 3 depicts a diagram of an exemplary embodiment of an active pixel sensor having two transistors. The transistors are preferably TFTs. The general operation of sensor pixel 300 as shown in FIG. 3 is as follows. Sensor pixel 300 can be reset to the reference voltage on the data line 320 by turning on reset transistor RST 308. Reset transistor RST 308 is turned ON by applying a positive voltage pulse to scan line SCANᵢ 316. This ensures that the gate 310 of amplifier transistor AMP 306 is reset prior to readout. For the analysis that follows, the reference voltage of the data line is taken to be zero. To read the pixel value, a positive voltage pulse is applied to scan line SCANᵢ₊₁ 318. Because the voltage at gate 310 is floating during readout, the voltage at the gate 310 of the amplifier transistor AMP 306 increases due to capacitive coupling of the voltage pulse through the capacitor 304 and results in switching the AMP transistor 306 from the OFF state to active saturation mode and conducting its drain current to the output 320.

The sensor pixel shown in FIG. 3 includes capacitive sensor 302. Although the sensor pixel in FIG. 3 reduces the number of transistors from three to two, its effectiveness for use with capacitive sensors had not previously been shown. To operate effectively with a capacitive sensor, the readout architecture must produce a signal that depends on the capacitance of the sensor, and preferably amplifies differences in sensor capacitance values while representing the instantaneous capacitance of the sensor (i.e., does not require integrating charge).

Sensor pixel 300 exhibits these properties. As shown in FIG. 3, sensor pixel 300 includes capacitive sensor 302 with varying capacitance C_{F}. Capacitive sensor 302 may be, for example, a fingerprint sensor that changes capacitance depending on whether it comes into contact with the ridge or the valley of a fingerprint. As shown in FIG. 3, only one plate of the capacitor 312 and its dielectric 314 are formed as part of the pixel. The fingerprint acts as the other plate, which is grounded. The capacitance of the sensor pixel is CF_{i,j}. When the ridge of the finger is placed against the pixel_{i,j}, the distance between the plates is td, or the thickness of the dielectric. This makes the capacitance CF_{i,j} equal to

$${ɛ}_{0} {ɛ}_{rd} \frac{A}{td} .$$

When the valley of a fingerprint is placed upon the pixel sensor, for example on pixel_{i,j-1}, then the capacitance CF_{i,j-1} becomes the series of two capacitances—one formed by the dielectric 314 and the other by the air gap between the dielectric and the valley of the fingerprint. This make the capacitance CF_{i,j-1} to be equal to

$${ɛ}_{0} {ɛ}_{rd} \frac{A}{td + {ɛ}_{rd} tv} ,$$

which is smaller than CF_{i,j}, when the pixel is in contact with the ridge of the fingerprint.

The capacitor 304 is a coupling capacitor with capacitance C_{C} that couples the readout pulse on the scan line 318 to the gate of amplifier transistor AMP 306. The effective capacitance at the node 310 (not including C_{C}) is the gate capacitance of amplifier transistor AMP 306, C_{G}_{_{—}}_{AMP} the drain-gate capacitance of the reset transistor RST 308, C_{DG}_{_{—}}_{RST} and the variable sensor capacitance of sensor 312, C_{F}. Therefore, when the readout pulse with the pulse height of V_{GHI} is applied to the scan line 318, the voltage V_{S} at the node 310, which is equal to the gate source voltage of the amplifier transistor AMP 306 assuming V_{GLO}=V_{DATA}=0, will be:

$${V}_{S} ( {C}_{F} ) = {V}_{GS\_AMP} = {V}_{GHI} \frac{{C}_{C}}{{C}_{F} + {C}_{C} + {C}_{G\_AMP} + {C}_{GD\_RST}} \qquad ( 1 )$$

The drain current of the amplifier transistor AMP 306 that flows to the output terminal 320 is represented by the following equation:

I_{OUT}=K_{AMP}[V_{GS}_{_{—}}_{AMP}−V_{T}]ⁿ,

where V_{GS}_{_{—}}_{AMP} is the voltage across the gate and source terminals of amplifier transistor AMP 306 defined by equation (1), and V_{T} is the threshold voltage of amplifier transistor AMP 306 (i.e., the minimum voltage difference across the gate and source terminals required for current to flow through the transistor), and the exponent n depends on the technology and the mode of operation of the transistor. For a TFT made from a-Si, n typically has a value of about 2 when the TFT operates in saturation mode. K_{AMP} is the scaling factor constant determined by the technology as well as the geometry of the transistor defined as

$$μ {C}_{0} \frac{W}{L} ,$$

where μ is the effective carrier mobility, C₀ is gate capacitance per unit area, and W/L is the transistor aspect ratio.

Combining equations (1) and (2) gives the output current in terms of the sensor capacitance C_{F} as follows:

$${I}_{OUT} ( {C}_{F} ) = {{K}_{AMP} ( \frac{{V}_{G} {C}_{C}}{{C}_{F} + {C}_{C} + {C}_{G\_AMP} + {C}_{DG\_RST}} - {V}_{T} )}^{n} \qquad ( 3 )$$

As indicated by equation (3), the output current of sensor pixel 300 has the desirable property of being inversely related to the sensor capacitance C_{F} 302. When the capacitance increases as a result of the sensor being in contact with a ridge of a fingerprint, the output current decreases, and when the capacitor decreases as a result of being in contact with the valley of a fingerprint, the output current increases.

The two-transistor active pixel sensor shown in FIG. 3 may also be used to create a two-dimensional array to form, for example, a fingerprint imaging array. FIG. 4A depicts an exemplary embodiment of an imaging array comprised of sensor pixels configured in the same manner as sensor pixel 300 shown in FIG. 3. As shown, the output of each sensor pixel in a column is connected to the data line designated for that column (i.e., DATAⱼ or DATAⱼ₊₁) and the coupling capacitor of each sensor pixel within a row is connected to the scan line designated for that row (i.e., SCANᵢ 402 or SCANᵢ₊₁ 404). In the embodiment shown in FIG. 4A, reset transistors 406 are controlled by the voltage at the scan line of the row immediately beneath them. Accordingly, when the voltage at SCANᵢ 402 is HIGH, the values of the sensor pixels in row i are being read, and the voltages at nodes V_{S} of the sensor pixels in row i+1 are reset to the voltage of the data line of their respective columns. This provides an automatic resetting scheme without the need for separate gate drivers for resetting pixel sensors.

An alternative resetting scheme is to connect the gates of all reset transistors together and provide a global reset line for the entire sensor array as shown in FIG. 4B. In this circuit the entire array may be reset prior to readout operation.

As shown in FIG. 4A and FIG. 4B, the output of the pixel array from each data line is connected to a trans-impedance amplifier that converts the pixel output current to a representative output voltage. Connecting the non-inverting input of the op-amp to the reference voltage V_{REF} ensures that the data line voltage is at voltage V_{REF} for resetting the pixels during the reset operation whether an automatic or global scheme is used. In these circuits, the pixel output is taken as current and is converted to a voltage using a trans-impedance amplifier. A skilled person in the field would understand that the output of the pixel could be taken as voltage (assuming the amplifier transistor acts as a source follower) and use a voltage buffer/amplifier at the end of each column for conditioning the output for analog to digital conversion.

One skilled in the field would recognize that the sensor pixels in an imaging array may have a different configuration for providing the reference voltage for resetting the sensor pixel, such as, for example, the sensor pixel architecture shown in FIG. 6 or FIG. 7 described in detail below. Also, the sensor pixels in separate rows and columns of an array may be connected in a manner other than that shown in FIG. 4A or FIG. 4B.

FIGS. 5A-C illustrate the configuration and response of a sensor pixel such as sensor pixel 300 shown in FIG. 3. FIG. 5A shows a diagram of a simulated APS circuit similar to sensor pixel 300 in FIG. 3 connected to external voltage sources for driving the pixel. The output of the pixel is virtually grounded as is the case when the output is connected to the inverting input terminal of the op-amp in FIG. 4A with R_{F} equal to 1MΩ. The external circuitry simulates the effects of additional circuitry to which the sensor pixel is attached when it is included in an imaging array such as, for example, imaging array 400 shown in FIG. 4A. For example, the resistors R_{DL} and capacitor C_{DL} represent the resistance and capacitance respectively of a data line column on an imaging array panel that spans across several rows of pixels. Similarly, resistors R_{SL} and capacitor C_{SL} represent the resistance and capacitance respectively of a scan line row on an imaging array panel that spans across several columns of pixels.

The performance of a sensor pixel represented by the diagram in FIG. 5A was simulated. The simulation used a 50 μm×50 μm sensor pixel and varied the capacitance C_{F} of the sensor from 10 fF at a valley of a fingerprint to 30 fF for a ridge. The coupling capacitor had a capacitance value of 25 fF. In this example, the TFTs were made from a-Si, and W/L was 20 μm/2 μm for the amplifier transistor and 2 μm/2 μm for the reset transistor. FIG. 5B depicts a plot of the voltage applied to the coupling capacitor with capacitance C_{C} as a function of time. Although not shown, the pulses are preceded by similar pulses at the reset line to reset the sensor pixel as described previously. FIG. 5C depicts a plot of the output voltage as a function of time. As mentioned previously, the output voltage was calculated as I_{OUT}×1 MΩ feedback resistance of a trans-impedance amplifier.

As shown in FIGS. 5B-C, applying a 15 V pulse at the scan line produced an output voltage slightly greater than 2.25 V for the valley of a fingerprint, and a response of approximately 1.0 V when there was a ridge. Thus, the circuit results in a greater than 2:1 valley-to-ridge output ratio. The detection response may be optimized by adjusting the parameters of various circuit elements such as the channel width of the amplifier transistor and the capacitance C_{C} of the coupling capacitor. Detection response may be optimized by maximizing the product of the difference between the valley and ridge outputs and the relative magnitude of the difference in response. The large difference in the output in response to the valley and the ridge of the fingerprint (2.5 V versus 1.0 V) in the simulated circuit is because of the use of the active pixel sensor. Simulating the passive pixel of the prior art shown in FIG. 1 resulted in much smaller difference in the output (1.2 V versus 1.0V) indicating that the output of passive pixel sensors are less sensitive to the capacitance changes of the capacitive fingerprint sensors.

FIG. 6 depicts another exemplary embodiment of a two-transistor active pixel sensor having a capacitive sensor. Sensor pixel 600 represented in FIG. 6 is similar to sensor pixel 300 shown in FIG. 3. The primary difference is that source terminal 604 of reset transistor RST 602 in FIG. 6 is connected to scan line SCANᵢ₊₁ 606 instead of output 608 as in FIG. 3. As a result, the reset voltage of the node V_{S} is the LOW voltage of scan line SCANᵢ₊₁ 606, V_{GLO}. Accordingly, amplifier transistor AMP 610 can have a negative voltage V_{GS} between its gate and source terminals when the voltage at scan line SCANᵢ₊₁ 606 is LOW if the reference voltage of the output is greater than V_{GLO}. A negative V_{GS} when the voltage at scan line SCANᵢ₊₁ 606 is LOW may provide better protection against leakage from node V_{S} and prevents amplifier transistor AMP 610 from inadvertently being turned ON. Additionally, the gate-source and gate-drain voltages of the reset transistor RST 602 will be 0.0 V when the voltage at scan lines SCANᵢ 612 and SCANᵢ₊₁ 606 are LOW, ensuring no leakage through the reset transistor 602.

FIG. 7 depicts another exemplary embodiment of a two-transistor active pixel sensor having a capacitive sensor. Sensor pixel 700 shown in FIG. 7 is similar to sensor pixels 300 and 600, except it has an independent voltage source V_{SS} for resetting the pixel sensor. The primary difference between sensor pixel 700 and sensor pixels 300 and 600 is that the source terminal 704 of reset transistor RST 702 in sensor pixel 700 is connected to the additional independent voltage source instead of output 708 as in sensor pixel 300 or a scan line as in sensor pixel 600. As a result, it is possible to have a negative voltage between the gate and source terminals for both the amplifier transistor AMP 710 and the reset transistor RST 702 when the voltage at scan lines 706 and 712 are LOW. A negative voltage between the gate and source terminals may be necessary, for example, if the threshold of the TFTs is negative.

The transistors in sensor pixels 300, 600, and 700 may be, for example, field effect transistors, thin film transistors, or the like. They may be formed from materials such as, for example, amorphous silicon, poly-silicon, amorphous metal oxide (e.g., IGZO), or the like. In addition, sensor pixels 600 and 700 may also be arranged in an array to form a fingerprint imaging array similar to imaging array 400 shown in FIG. 4A and FIG. 4B.

FIG. 8 represents the diagram of a fingerprint imaging detector panel 810 having a capacitive pixel sensor 820, TFT gate driving modules 830 that provides driving pulses for scan lines 840 of the sensor array, and TFT column multiplexing modules 860 that multiplex sensor array outputs 850 and connect them to the signal processing and ADC unit 880 for conditioning and conversion into digital information. The sensor array 820, the gate driver 830 and the multiplexing modules 860 are made from TFTs and are formed on the same substrate panel. The supply voltages and control signals for the operation of the fingerprint detector 800 are provided by signal source 870. Alternatively, the fingerprint sensor array can be connected to external gate driver and multiplexing modules as shown in FIG. 9. In this configuration it is desirable to employ gate drivers 930 and multiplexers 960 that are made using a technology (for example CMOS) that is different from the one used for fabricating the sensor array 920 (for example a-Si or amorphous metal oxide semiconductor).

The foregoing descriptions of specific embodiments have been presented for purposes of illustration and description. They are not intended to be exhaustive or to limit the invention to the precise forms disclosed, and it should be understood that many modifications and variations are possible in light of the above teaching.

We claim:

1. A fingerprint sensor pixel comprising:
a capacitive sensor, wherein a capacitance of the capacitive sensor changes in response to contact with the valley or the ridge a fingerprint; and
a readout circuit comprising:
a first thin film transistor (TFT) having a gate terminal, a drain terminal, and a source terminal, wherein the gate terminal of the first TFT is coupled to the capacitive sensor; and
a coupling capacitor having a first terminal and a second terminal, wherein the first terminal of the coupling capacitor is coupled to the gate terminal of the first TFT,
wherein the readout circuit is configured to generate, in response to a voltage applied to the second terminal of the coupling capacitor, a current flow between the drain terminal of the first TFT and the source terminal of the first TFT representative of the capacitance of the capacitive sensor.

2. The fingerprint sensor pixel of claim 1, further comprising:
a second TFT having a gate terminal, a drain terminal, and a source terminal, wherein the drain terminal of the second TFT is coupled to the gate terminal of the first TFT, and
wherein the readout circuit is further configured to set the voltage at the gate terminal of the first TFT to the value of the voltage at the source terminal of the second TFT in response to a voltage applied to the gate terminal of the second TFT.

3. The fingerprint sensor pixel of claim 2, wherein the readout circuit is configured such that the source terminal of the second TFT is coupled to an output line that receives the signal representative of the capacitance of the capacitive sensor.

4. The fingerprint sensor pixel of claim 2, wherein the source terminal of the second TFT is coupled to an independent voltage source.

5. A fingerprint imaging device comprising:
a plurality of fingerprint sensor pixels forming a two-dimensional fingerprint sensor array, each fingerprint sensor pixel of the plurality of fingerprint sensor pixels comprising:
a capacitive sensor, wherein the capacitance of the capacitive sensor changes in response to contact with a fingerprint; and
a readout circuit comprising:
a first thin film transistor (TFT) having a gate terminal, a drain terminal, and a source terminal, wherein the gate terminal of the first TFT is coupled to the capacitive sensor; and
a coupling capacitor having a first terminal and a second terminal, wherein the first terminal of the coupling capacitor is coupled to the gate terminal of the first TFT,
wherein the readout circuit is configured to generate, in response to a voltage applied to the second terminal of the coupling capacitor, a current flow between the drain terminal of the first TFT and the source terminal of the first TFT representative of the capacitance of the capacitive sensor.

6. The fingerprint imaging device of claim 5, wherein the readout circuit further comprises:
a second TFT having a gate terminal, a drain terminal, and a source terminal,
wherein the drain terminal of the second TFT is coupled to the gate terminal of the first TFT, and wherein the readout circuit is further configured to set the voltage at the gate terminal of the first TFT to the value of the voltage at the source terminal of the second TFT in response to a voltage applied to the gate terminal of the second TFT.

7. The fingerprint imaging device of claim 6, wherein the readout circuit is configured such that the source terminal of the second TFT is coupled to an output line that receives the signal representative of the capacitance of the capacitive sensor.

8. The fingerprint imaging device of claim 6, wherein the source terminal of the second TFT is coupled to an independent voltage source.

9. The fingerprint imaging device of claim 6, further comprising a scan line associated with each row of fingerprint sensor pixels, wherein a scan line associated with a row is coupled to a second terminal of a coupling capacitor of a fingerprint sensor pixel in the associated row and to a gate terminal of a second TFT in a row adjacent to the associated row.

10. The fingerprint imaging device of claim 6, further comprising:
a scan line associated with each row of fingerprint sensor pixels, wherein a scan line associated with a row is coupled to a second terminal of a coupling capacitor of a fingerprint sensor pixel in the associated row; and
a reset line coupled to the gate terminal of the second TFT of each fingerprint sensor pixel.

11. The fingerprint imaging device of claim 5, further comprising:
at least one gate driver module operatively coupled to the fingerprint sensor array, the at least one gate driver module configured to apply a voltage to the coupling capacitors of the plurality of fingerprint sensor pixels; and
at least one multiplexing module operatively coupled to the fingerprint sensor array, the at least one multiplexing module configured to multiplex signals representative of the capacitance of the capacitive sensors from the plurality of fingerprint sensor pixels.

12. The fingerprint imaging device of claim 11, further comprising a substrate panel, wherein the fingerprint sensor array, the at least one gate driver module, and the at least one multiplexing module are formed on the substrate panel.

13. A fingerprint imaging device comprising:
a plurality of fingerprint sensor pixels forming a two-dimensional fingerprint sensor array, each sensor pixel including:
a capacitive sensor, wherein the capacitance of the capacitive sensor changes in response to contact with a fingerprint;
a first transistor coupled to the capacitive sensor at a first node, said first transistor for amplifying the change in capacitance of the capacitive sensor;
a coupling capacitor coupled to the first node, said coupling capacitor being responsive to a scan signal which causes the first transistor to generate an output proportional to the change in capacitance of the capacitive sensor; and
a reset transistor coupled to the first node and responsive to a reset signal for resetting the voltage of the first node.

14. The fingerprint imaging device of claim 13, wherein the first node is reset to the voltage of the output of the first transistor.

15. The fingerprint imaging device of claim 13, wherein the first node is reset to the voltage of the scan signal.

16. The fingerprint imaging device of claim 13, wherein the first node is reset to an independent voltage source.

17. The fingerprint imaging device of claim 13, wherein a signal at the first node is proportional to the change in capacitance of the capacitive sensor, and the output is proportional to the signal at the first node.

18. The fingerprint imaging device of claim 13, wherein the scan signal causes the first transistor in a first sensor pixel in a first row of sensor pixels to generate an output proportional to the change in capacitance of the capacitive sensor of the first sensor pixel, and resets the first node of a second sensor pixel in a second row of sensor pixels adjacent to the first row.

19. The fingerprint imaging device of claim 13, wherein the fingerprint imaging device is configured to reset the first node of each sensor pixel in response to a global reset signal.

20. The fingerprint imaging device of claim 13, further comprising:
at least one gate driver module operatively coupled to the fingerprint sensor array, the at least one gate driver module configured to apply scan signals to the coupling capacitors of the plurality of fingerprint sensor pixels; and
at least one multiplexing module operatively coupled to the fingerprint sensor array, the at least one multiplexing module configured to multiplex signals representative of the capacitance of the capacitive sensors from the plurality of fingerprint sensor pixels.

21. The fingerprint imaging device of claim 20, further comprising a substrate panel, wherein the fingerprint sensor array, the at least one gate driver module, and the at least one multiplexing module are formed on the substrate panel.
